(19) United States
(12) Patent Application Publication
(10) Pub. No.: US 2010/0282301 A1
(43) Pub. Date: Nov. 11, 2010

(54) GLASS SUBSTRATE COATED WITH LAYERS HAVING IMPROVED RESISTIVITY

(75) Inventors: Emmanuelle Peter, Paris (FR); Eric Gouardes, Toulouse (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: Saint-Gobain Glass France, Courbevoie (FR)

(21) Appl. No.: 12/739,822

(22) PCT Filed: Oct. 22, 2008
(86) PCT No.: PCT/FR2008/051904

§ 371 Date: Jul. 22, 2010

(30) Foreign Application Priority Data
Oct. 25, 2007 (FR) 0758571

(51) Int. Cl. H01L 31/0224; B32B 15/04

(52) U.S. Cl. 136/252; 428/433; 428/336

(57) ABSTRACT

A transparent glass substrate, associated with a stack of thin layers forming an electrode, the stack comprising a barrier underlayer that is a barrier to alkalis, and an electroconductive layer, said electroconductive layer being coated with an overlayer for protection against oxidation, characterized in that the stack comprises a metallic blocking layer capable of being oxidized during a heat treatment.

The present invention relates to transparent conductive layers, notably based on oxides, of considerable value on a glass substrate. These transparent layers are generally called TCO for “Transparent Conductive Oxide”.

Examples of these are layers of indium oxide doped with tin (ITO, Indium Tin Oxide), layers of tin oxide doped with fluorine (SnO₂:F), or layers based on zinc oxide doped with aluminum (ZnO:Al) or doped with boron (ZnO:B).

These materials are generally deposited by a chemical process, as for example by chemical vapor deposition (CVD), possibly plasma enhanced (PECVD), or by a physical process, as for example by vacuum cathodic sputtering deposition, possibly assisted by a magnetic field (Magnetron sputtering).

However, in order to obtain the desired electrical conduction, or rather the desired low resistance, the electrode coating based on TCO should be deposited at a relatively high physical thickness, of the order of a few hundred nanometers, which is costly considering the price of these materials when they are deposited in thin films.

Currently, in order to obtain optimum electrical properties, TCOs are deposited while hot. However, such deposition method requires provision of heat, which increases the manufacturing costs still further.

Another major disadvantage of electrode coatings based on TCO lies in the fact that for a chosen material its physical thickness is always a compromise between the electrical conduction finally obtained and the transparency finally obtained, since the greater the physical thickness the higher the conductivity but the lower the transparency, and conversely, the lower the physical thickness the greater the transparency but the lower the conductivity.

It is therefore not possible, with electrode coatings based on TCO, to optimize the conductivity of the electrode coating and its transparency independently.

Another problem of TCOs comes from their use in many products as an electrode in various applications: flat lamps, electroluminescent glazings, electrochromic glazings, liquid crystal display screens, plasma screens, photovoltaic cells, heating glazings, low emissivity glazings.

In order to give a glass substrate its mechanical strength, many of these products must undergo heat treatment, such as for example toughening. During toughening, the stack is brought to approximately 620° C. for a few minutes in an ambient atmosphere. Unfortunately, the electrical properties of most TCOs deteriorate drastically during this toughening on account of the oxidation of the TCO and the migration of alkalis from the glass.

Existing solutions (described for example in WO2007018951, or US20070029186) propose to encapsulate the TCO in barrier layers protecting against the migration of alkalis (thanks to the underlayer) and oxidation (thanks to the overlayer). However, although these barrier layers enable the deterioration of the TCO to be moderated during toughening, they do not improve it.

The object of the present invention is therefore to overcome the disadvantages of the preceding techniques by providing a solution for a TCO of which both the optical and electrical conduction properties are not affected by the heat treatment phases, and are even improved by the latter.

The object of the invention is therefore a transparent glass substrate, associated with a stack of thin layers forming an electrode, the stack comprising a barrier underlayer that is a barrier to alkalis, an electroconductive layer, said electroconductive layer being coated with an overlayer for protection against oxidation, characterized in that the stack comprises a metallic blocking layer capable of being oxidized during a heat treatment.

By virtue of the presence of this blocking layer, it is possible to obtain, by a cold deposition method, performances that are identical to those that would have been obtained by a hot deposition method, and the performances obtained after heat treatment are improved compared with those obtained before heat treatment.

In preferred embodiments of the invention, it is possible to make use of one or other of the following arrangements:
the metallic blocking layer is based on titanium, chromium, nickel, niobium, zinc, tin, used alone or mixed,
the thickness of the metallic blocking layer lies between 0.5 and 20 nm, preferably between 0.5 and 10 nm,
the metallic blocking layer is situated below the electroconductive layer,
the metallic blocking layer is situated above the electroconductive layer,
a blocking layer is situated above and below the electroconductive layer, the materials forming each of the blocking layers being identical,
a blocking layer is situated above and below the electroconductive layer, the materials forming each of the blocking layers being different,
the barrier underlayer is based on a dielectric material,
the dielectric material is based on silicon nitrides, oxides or oxynitrides, or on aluminum nitrides, oxides or oxynitrides, or on titanium nitrides, oxides or oxynitrides, or on zirconium nitrides, oxides or oxynitrides, used alone or mixed,
the thickness of the barrier underlayer lies between 3 and 250 nm, preferably between 10 and 200 nm, and substantially close to 20 to 25 nm,
the overlayer for protection against oxidation is identical to the alkali barrier underlayer,
the electroconductive layer is based on an oxide doped with Sn, Zn, Ti or In, such as SnO₂:F, SnO₂:Sb, ZnO:Al, ZnO:Ga, InO:Sn, ZnO:In or TiO₂:Nb.

In this way, the invention makes it possible to obtain stacks of layers suitable for photovoltaic cells, of which the mechanical strength on the glass substrate is not affected in the presence of an electric field and at a high temperature. This considerable improvement may be obtained for large glass areas (full-width float, in French PLF), since deposition procedures compatible with such dimensions are available for the layers concerned.

In addition, as regards the electrical properties, the resistivity of the electrode is improved after having undergone a heat treatment. In this way, the transparent electroconductive layer of the substrate of the invention is not only able to constitute a photovoltaic cell electrode.

Subsidiarily, the transparent substrate of the invention has improved optical properties compared with those of transparent electroconductive layers on glass substrate: reduced iridescence, more uniform colorimetry in reflection, increased transmission.

An element capable of collecting light (a solar or photovoltaic cell) will be described hereinafter.

The transparent substrate with a glass function may for example be made of glass containing alkalis such as a soda-lime-silica glass. It may also be a thermoplastic polymer such as a polyurethane or a polycarbonate or a polymethyl methacrylate.

Most of the weight (that is to say at least 98% by weight) or even the totality of the substrate with a glass function is made of a material or materials having the best possible transparency and preferably having a linear absorption less than 0.01 mm⁻¹ in the part of the spectrum useful for the application (solar module), generally the spectrum extending from 380 to 1200 nm.

The substrate may have a total thickness extending from 0.5 to 10 mm when it is used as a protective plate for a photovoltaic cell of various chalcopyrite technologies (CIS, CIGS, CIGSe₂, etc.), or a photovoltaic cell belonging to a silicon-based technology, it being possible for the latter to be amorphous or microcrystalline, or a photovoltaic cell belonging to a technology using cadmium telluride (CdTe).

Another family of absorber agent also exists based on wafers of polycrystalline silicon, deposited in the form of a thick layer, with a thickness of between 50 μm and 250 μm.

When the substrate is used as a protective plate, it may be advantageous to subject this plate to a heat treatment (of the toughening type for example) when it is made of glass.

Conventionally, the front face of the substrate directed towards the light rays (i.e. the outer face) is denoted A, and the rear face of the substrate directed towards the remainder of the layers of the solar module (i.e. the inner face) is denoted B.

The face B of the substrate is coated with a stack of thin layers according to the procedures of the invention.

In this way, at least one portion of the surface of the substrate is coated with a barrier layer that is a barrier to alkalis. This alkali barrier layer is based on a dielectric material, this dielectric material being based on silicon nitrides, oxides or oxynitrides, or based on aluminum nitrides, oxides or oxynitrides, or based on zirconium nitrides, oxides or oxynitrides, used alone or mixed. The thickness of the barrier layer lies between 3 and 200 nm, preferably between 10 and 100 nm, and substantially close to 20 to 25 nm.

This alkali barrier layer, for example based on silicon nitride, may not be stoichiometric. It may be by nature sub-stoichiometric, or even over-stoichiometric.

The presence of this barrier layer on face B of the substrate makes it possible to avoid or even to block the diffusion of Na from the glass towards the upper active layers.

An electroconductive layer made of TCO (Transparent Conductive Oxide) is deposited on this barrier layer. It may be chosen from the following materials: doped tin oxide, in particular doped with fluorine or antimony (precursors that can be used in the case of CVD deposition may be tin organometallics or halides associated with a fluorine precursor of the fluoric acid or trifluoroacetic acid type); doped zinc oxide, in particular doped with aluminum (precursors that can be used in the case of CVD deposition may be zinc and aluminum oganometallics or halides); or doped indium oxide, in particular doped with tin (the precursors that can be used in the case of CVD deposition may be tin and indium organometallics or halides).

As a variant, the TCO layer for example made of ZnO may also be deposited by sputtering using a metallic or ceramic target.

This conductive layer should also be as transparent as possible, and have a high light transmission in all wavelengths corresponding to the absorption spectrum of the material constituting the functional layer, so as not to reduce unnecessarily the energy conversion efficiency of the solar module. The thickness of this electroconductive layer lies between 50 and 1500 nm, preferably between 200 and 800 nm, and substantially close to 500 nm.

The conductive layer has a sheet resistance of at most ohms per square, notably of at most 30 ohms per square.

The electroconductive layer is then covered with a layer for protection against oxidation similar to the barrier layer for protection against the migration of alkalis. Having a substantially similar constitution and thickness, it may not be stoichiometric.

According to an advantageous feature of the invention, at least one metallic blocking layer is incorporated in the stack forming the electrode, which will have the possibility of being oxidized, and of creating an oxide layer of the metal in question during heat treatment of the electrode, more exactly during for example the toughening of the substrate coated with said electrode.

The metallic blocking layer will be based on titanium, nickel, chromium, niobium, used alone or mixed.

This blocking layer is, according to an embodiment of the invention, situated below the electroconductive layer and in contact with the alkali barrier layer or, according to another embodiment of the invention, situated above the electroconductive layer and thus in contact with the layer for protection against oxidation or, according to another embodiment variant, situated above and below the electroconductive layer.

Similarly, according to variant embodiments of the invention, the blocking layers situated above and below will consist of an identical material or of different materials.

The thickness of this metallic blocking layer lies between 0.5 and 20 nm, preferably between 0.5 and 10 nm.

The stack of thin layers produced in this way and forming an electrode is covered with a functional layer based on an absorber agent permitting energy conversion between light rays and electrical energy.

It will be possible to use, as a functional layer, either a chalcopyrite absorber agent, based for example on CIS, CIGS or CIGSe₂, or based on a silicon-based absorber agent, as for example a thin layer based on amorphous silicon or micro-crystalline silicon, or an absorber agent based on cadmium telluride.

In order to form the second electrode, the functional layer is covered with a conductive layer, possibly transparent, conventionally of the TCO type, or of a non-transparent type, as for example one based on molybdenum, as a metallic material or metallic oxide. Conventionally, this electrode layer is based on ITO (Indium Tin Oxide), or made of metal (silver, copper, aluminum, molybdenum), or made of tin oxide doped with fluorine, or made of doped zinc oxide.

The assembly of thin layers is trapped between two substrates via a lamination interlayer or encapsulant, for example made of PU, PVB or EVA, in order to form the solar cell.

Examples of the prior art are given below.

| | Sheet | Sheet | Light | Light |
|---|---|---|---|---|
| | resistance | resistance | absorption | absorption |
| | before | after | before | after |
| Si3N4:ZnO: | toughening | toughening | toughening | toughening |
| Si3N4 | (ohms) | (ohms) | (%) | (%) |
| 150:200:150 | 110 | 80 | 5.2 | 2 |
| (in nm) | | | | |
| 50:200:50 | 115 | 145 | 5.2 | 1.5 |
| (in nm) | | | | |

As may be seen in these examples of the prior art, the sheet resistance may be improved after toughening only if the barrier layers, that are barriers to oxidation and alkalis, are thick. In this case, there is an increased risk of delamination of the layers-problem of adhesion to the substrate-, this delamination being observable visually.

Examples of embodiments according to the invention are given below.

| | Sheet | Sheet | Light | Light |
|---|---|---|---|---|
| | resistance | resistance | absorption | absorption |
| | before | after | Before | after |
| Si3N4:Ti:ZnO: | toughening | toughening | toughening | toughening |
| (Ti):Si3N4 | (ohms) | (ohms) | (%) | (%) |
| 25:2:200:25 | 110 | 30 | 16 | 3.8 |
| (in nm) | | | | |
| 25:2:200:2:25 | 110 | 30 | 15.6 | 3 |
| (in nm) | | | | |

Resistivity is remarkably reduced after toughening compared with examples of the prior art. It will be noted that this improvement in electrical properties is not made to the detriment of mechanical properties (no delamination problem), the thickness of the alkali barrier layer and of the layer for protection against oxidation being noticeably less than those used in the prior art.

It may be noted that similar results are obtained by using a layer of ITO (Indium Tin Oxide), instead of the metallic blocking layer made of titanium, or nickel, or chromium, or niobium, nevertheless with a little greater thickness, corresponding substantially to 10% of the thickness of the conductive layer, for example made of zinc oxide.

Other examples will be given of embodiments according to the invention, showing that similar results are obtained with another material for the blocking layer.

Another advantage of the invention may be noted, namely that the light transmission is remarkably improved after toughening.

| | | | | | |
|---|---|---|---|---|---|
| Si3N4:Ti:ZnO: | Thicknesses in | Sheet | Sheet | TL before | TL after |
| Si3N4 | nm | resistance | resistance | toughening | toughening |
| | 25:2:500:25 | before | after | 72% | 85.7% |
| | | toughening | toughening | | |
| | | (ohms) 33 | (ohms) 10 | | |
| Si3N4:Ti:ZnO: | Thicknesses in | Sheet | Sheet | TL before | TL after |
| Ti:Si3N4 | nm | resistance | resistance | toughening | toughening |
| | 15:2:500:2:25 | before | after | 65.9% | 84.9% |
| | | toughening | toughening | | |
| | | (ohms) 40 | (ohms) 15.5 | | |

The following examples demonstrate the advantage obtained on account of the presence of a blocking layer below the electroconductive layer.

### EXAMPLE 1

### State of the Art: Encapsulation of AZO in Si3N4 for Withstanding Toughening

| | Thickness | Rsq | rho | TL | Rsq | rho | TL |
|---|---|---|---|---|---|---|---|
| Stack | in nm | (ohm) | (μohm · cm) | (%) | (ohm) | (μohm · cm) | (%) |
| Si3N4:AZO: | 150:200:50 | 110 | 2200 | 77.2 | 28 | 560 | 85 |
| Si3N4 Si3N4 | | | | | | | |

Example 2 showing that reduction in the lower Si3N4 leads to an increase in Rsq after toughening.

| | Thickness | Rsq | rho | TL | Rsq | rho | TL |
|---|---|---|---|---|---|---|---|
| Stack | in nm | (ohm) | (μohm · cm) | (%) | (ohm) | (μohm · cm) | (%) |
| Si3N4:AZO: | 150:200:50 | 110 | 2200 | 77.2 | 28 | 560 | 85 |
| Si3N4 Si3N4 | | | | | | | |
| Si3N4:AZO: | 25:200:25 | 140 | 2800 | 75.4 | 37.5 | 750 | 83.4 |
| Si3N4 Si3N4 | | | | | | | |

Example 3 showing that adding a blocking layer below the electroconductive layer makes it possible to reduce the thickness of the lower Si3N4 to 25 nm without increasing the Rsq.

Moreover, this example shows that, contrary to the lower Si3N4, the thickness of the upper Si3N4 may be reduced without affecting the Rsq at 25 nm, which also shows that a blocking layer positioned above the electroconductive layer is not absolutely necessary.

| | Thickness | Rsq | rho | TL | Rsq | rho | TL |
|---|---|---|---|---|---|---|---|
| Stack | in nm | (ohm) | (μohm · cm) | (%) | (ohm) | (μohm · cm) | (%) |
| Si3N4:AZO: | 150:200:50 | 110 | 2200 | 77.2 | 28 | 560 | 85 |
| Si3N4 56/40 Si3N4 | | | | | | | |
| Si3N4:Ti:AZO:Si3N4 | 25.2:200:25 | 110 | 2200 | 75.4 | 29 | 580 | 86.6 |

1. A transparent glass substrate, having a stack of thin layers forming an electrode, the stack comprising a barrier underlayer that is a barrier to alkalis, an electroconductive layer, said electroconductive layer being coated with an overlayer for protection against oxidation, wherein the stack comprises a metallic blocking layer capable of being oxidized during a heat treatment, the blocking layer being situated below the electroconductive layer.

2. The substrate as claimed in claim 1, wherein the metallic blocking layer comprises titanium, chromium, nickel, niobium, zinc, tin, or a mixture thereof.

3. The substrate as claimed in claim 1, wherein a thickness of the metallic blocking layer is between 0.5 and 20 nm.

4. The substrate as claimed in claim 1, wherein a metallic blocking layer is situated above the electroconductive layer.

5. The substrate as claimed in claim 1, wherein a blocking layer is situated above and another blocking layer is situated below the electroconductive layer, the materials forming each of the blocking layers being different.

6. The substrate as claimed in claim 1, wherein the barrier underlayer comprises a dielectric material.

7. The substrate as claimed in claim 1, wherein the dielectric material comprises at least one of silicon nitrides, oxides or oxynitrides, aluminum nitrides, oxides or oxynitrides, titanium nitrides, oxides or oxynitrides, zirconium nitrides, oxides or oxynitrides, and a mixture thereof.

8. The substrate as claimed in claim 1, wherein a thickness of the barrier underlayer is between 3 and 250 nm.

9. The substrate as claimed in claim 1, wherein the overlayer for protection against oxidation is identical to the alkali barrier underlayer.

10. The substrate as claimed in claim 1, wherein the electroconductive layer comprises an oxide doped with Sn, Zn, Ti or In.

11. The substrate as claimed in claim 1, wherein a thickness of the electroconductive layer is between 50 and 1500 nm.

12. The substrate as claimed in claim 1, wherein a resistivity of the electrode is reduced after having been subjected to the heat treatment.

13. A photovoltaic cell comprising a substrate according to claim 1.
